(19) United States
(12) Patent Application Publication
(10) Pub. No.: US 2025/0154982 A1
(43) Pub. Date: May 15, 2025

(54) MAGNETIC LEVITATION DEVICE

(71) Applicant: Levitronix GmbH, Zürich (CH)

(72) Inventors: Marcel STETTLER, Zofingen (CH); Thomas SCHNEEBERGER, Bern (CH); Natale BARLETTA, Zürich (CH); Patrick HINNI, Netstal (CH)

(21) Appl. No.: 18/931,264

(22) Filed: Oct. 30, 2024

(30) Foreign Application Priority Data
Nov. 15, 2023 (EP) 23210164.2

(51) Int. Cl. F16C 32/04

(52) U.S. Cl. CPC F16C 32/0451; F16C 2380/26

(57) ABSTRACT

A magnetic levitation device includes a housing, a stator and a controller. The stator includes coil cores having longitudinal and transverse legs and a winding at each longitudinal leg. The stator has a recess for the rotor. The controller includes a circuit board with front and back sides, with circuit breakers arranged on the front side. The housing includes an outer wall, a stator housing, a control housing, and a separating wall separating the stator housing from the control housing. A web is arranged on the separating wall adjacent to the outer wall, projecting into the control housing. The back side of the circuit board is supported on the web. The circuit breakers are arranged in an area with which the back side of the circuit board is supported on the web. The thermal connecting elements for dissipating heat are between the plurality of circuit breakers and the web.

### PRIORITY

This application claims priority to European Application No. 23210164.2, filed Nov. 15, 2023, the contents of which are hereby incorporated by reference.

### BACKGROUND

### Technical Field

The disclosure relates to a magnetic levitation device according to the preamble of the independent patent claim.

### Background Information

Generally magnetic bearing devices for contactless magnetic bearing of a rotor have the advantage that they do not require mechanical bearings for the rotor. The rotor is supported or stabilized by magnetic forces generated by a stator of the magnetic bearing device. Due to the absence of mechanical bearings, such magnetic bearing devices are in particular suitable for pumping, mixing, centrifuging or stirring devices, with which very sensitive substances are conveyed, for example blood pumps, or on which very high demands are made with respect to purity, for example in the pharmaceutical industry or in the biotechnological industry, or with which abrasive or aggressive substances are conveyed, which would very quickly destroy mechanical bearings, for example pumps or mixers for slurry, sulfuric acid, phosphoric acid or other chemicals in the semiconductor industry.

In the biotechnological industry, such magnetic bearing devices are used, for example, in connection with bioreactors, e.g. in centrifugal pumps for conveying the fluids into or out of the bioreactor, or in mixing devices which mix the fluids in the bioreactor. In the semiconductor industry, such magnetic bearing devices are not only used for conveying aggressive or abrasive substances, but also, for example, for rotation devices with which wafers are rotated.

It is also known to use magnetic bearing devices for viscometers.

### SUMMARY

An advantageous and design known per se of a magnetic bearing device is the design in temple construction, to which the present disclosure also relates.

The characteristic feature of the temple construction is that the stator of the magnetic bearing device has a plurality of coil cores, each of which comprises a longitudinal leg extending from a first end in an axial direction to a second end. Here, the axial direction refers to that direction which is defined by the desired axis of rotation of the rotor, which is supported by the magnetic bearing device. The desired axis of rotation is that axis of rotation about which the rotor rotates in the operating state when it is in a centered and non-tilted position with respect to the stator. Each coil core comprises, in addition to the longitudinal leg, a transverse leg, which is arranged in each case at the second end of the longitudinal leg, and which extends in the radial direction—usually towards inside—, wherein the radial direction is perpendicular to the axial direction. Thus, the transverse leg extends substantially at a right angle to the longitudinal leg. The coil cores each have the shape of an L, wherein the transverse legs form the short legs of the L. The rotor to be supported is then arranged between the transverse legs.

The plurality of the longitudinal legs which extend in the axial direction, and which are reminiscent of the columns of a temple has given this construction its name.

In one design, the stator of the magnetic bearing device has, for example, six coil cores which are arranged circularly and equidistantly around a cup-shaped recess into which the rotor can be inserted. The first ends of the longitudinal legs are usually connected in the circumferential direction by a back iron, which serves to conduct the magnetic flux. The rotor to be supported comprises a magnetically effective core, for example a permanent magnetic disk or a permanent magnetic ring, which is arranged between the radially inward ends of the transverse legs, and which rotates about the axial direction in the operating state, wherein the rotor is magnetically supported without contact with respect to the stator.

For such magnetic bearing devices, it is not necessarily the case that the magnetically effective core of the rotor must be designed in a permanent magnetic manner. There are also known such designs in which the magnetically effective core of the rotor is designed in a permanent magnetic-free manner, i.e., without permanent magnets. Then, the magnetically effective core of the rotor is, for example, designed in a ferromagnetic manner and is made, for example, of iron, nickel-iron, cobalt-iron, silicon iron, mu-metal, or another ferromagnetic material.

Furthermore, designs are possible in which the magnetically effective core of the rotor comprises both ferromagnetic materials and permanent magnetic materials. For example, permanent magnets can be placed or inserted into a ferromagnetic base body. Such designs are advantageous, for example, if one wishes to reduce the costs of large rotors by saving permanent magnetic material.

The longitudinal legs carry windings to generate the electromagnetic fields necessary for the contactless magnetic bearing of the rotor. For example, the windings are designed such that one concentrated winding is wound around each longitudinal leg, i.e., the coil axis of each concentrated winding extends in each case in the axial direction. Here, it is typical for the temple construction that the coil axes of the concentrated windings run in the axial direction and that the concentrated windings are not arranged in the radial plane in which the rotor or the magnetically effective core of the rotor is supported in the operating state.

Designs are possible in which exactly one concentrated winding is arranged on each longitudinal leg. In other designs, several, for example exactly two, concentrated windings are provided on each longitudinal leg. Designs are also possible in which windings are provided that are wound around two longitudinal legs that are adjacent in the circumferential direction, so that these two adjacent longitudinal legs are both located in the interior space of the concentrated winding.

Usually, the magnetic bearing device comprises a control unit which comprises the power electronics for controlling and supplying the windings of the stator, such as power converters or inverters for providing the current to be impressed into the windings or circuit breakers with which the windings are controlled. With regard to the most compact design possible and a lowest possible complexity of the magnetic bearing device, attempts have also been made to arrange the control unit as close as possible to the stator. In this case, however, considerable thermal problems arise because the control unit in particular also produces large amounts of heat in the operating state, which are difficult to dissipate.

In the control unit, it is the power electronics in particular, for example the circuit breakers for controlling the windings, which generate a considerable amount of heat during operation. If the motor unit and the control unit are therefore arranged close to each other, there is the risk that the heat generated during operation cannot be dissipated sufficiently well, which can lead to overheating of the electronic components in particular, which significantly reduces their service life.

Starting from this state of the art, it is therefore an object of the disclosure to propose a magnetic levitation device for contactless magnetic levitation of a rotor with a ring-shaped or disk-shaped magnetically effective core, which has a particularly compact design, wherein the control unit is reliably protected against overheating.

The subject matter of the disclosure meeting this object is characterized by the features disclosed herein.

According to the disclosure, a magnetic levitation device is thus proposed for contactless magnetic levitation of a rotor comprising a disk-shaped or ring-shaped magnetically effective core, wherein the magnetic levitation device comprises a housing, a stator, and a control device. The stator comprises a plurality of coil cores, each of which has a longitudinal leg extending from a first end in an axial direction to a second end, and a transverse leg which is arranged at the second end of the longitudinal leg, and which extends in a radial direction perpendicular to the axial direction, wherein at least one concentrated winding is provided at each longitudinal leg, which winding surrounds the respective longitudinal leg, wherein the stator further has a cup-shaped recess into which the rotor can be inserted, wherein the cup-shaped recess is arranged at an axial end of the stator. The control unit comprises a circuit board with a front side and a back side, wherein circuit breakers for controlling the windings are arranged on the front side. The housing comprises an outer wall, a stator housing for receiving the stator, a control housing for receiving the control unit, and a separating wall which separates the stator housing from the control housing. At least one web is arranged on the separating wall and adjacent to the outer wall, which web projects into the control housing, wherein the back side of the circuit board is supported on the web, wherein a plurality of the circuit breakers is arranged in the area of the circuit board with which the back side of the circuit board is supported on the web, and wherein thermal connecting elements for dissipating heat are provided between the plurality of circuit breakers and the web.

Due to this special arrangement of the circuit breakers in combination with the thermal connecting elements, it is possible to dissipate the heat generated by the circuit breakers in a particularly efficient manner via the thermal connections and the at least one web as well as the separating wall into the outer wall of the housing, from where the heat is then released to the environment, for example via convection. Due to this efficient heat dissipation of the heat generated by the circuit breakers, the electronic components of the control unit are reliably protected against overheating. Since the circuit breakers for controlling the windings are usually one, if not the main source of heat in the control unit, the reliable dissipation of the heat generated by the circuit breakers is an essential aspect for the longevity and operational safety of the magnetic levitation device.

Since the control unit and the stator are both arranged in the housing of the magnetic levitation device, the magnetic levitation device according to the disclosure is characterized by a very compact and space-saving design.

The thermal connecting elements are particularly preferably designed as through-hole platings, which are also designated as thermal vias. Usually, we define a thermal via as a hole that extends from the front side of the circuit board through the circuit board to the back side of the circuit board. The heat generated by the electronic components arranged on the front side of the circuit board can be dissipated via the thermal vias to the back side of the circuit board, where it is then absorbed by a heat sink.

The circuit breakers are those electronic components with which the windings of the stator are controlled and supplied with energy. The circuit breakers typically comprise transistors, preferably MOSFETs, with which half bridges or full bridges are realized that control the windings of the stator. Typically, one or more such half-bridge or full-bridge circuits are arranged in a chip housing of the circuit breaker, wherein drivers can optionally also be provided in the chip housing. The chip housing of the circuit breaker is then attached to the front side of the circuit board by a so-called die attach paddle (DAP). Several connection pins are provided at the chip housing of the circuit breaker, via which the electronic components of the circuit breaker, i.e., for example the transistors, can be electrically connected to conductor tracks or electrical connectors on the circuit board. The chip housings are attached to the circuit board by adhesives or by a soldered connection, for example.

In a preferred embodiment of the magnetic levitation device, the outer wall of the housing, the separating wall and the web are designed as a single-piece unit. This enables a particularly compact design and an efficient heat dissipation via the housing.

Preferably, each circuit breaker is arranged on a separate mounting surface, wherein each mounting surface is connected to the back side of the circuit board via a plurality of the thermal connecting elements, and wherein each thermal connecting element extends from the front side to the back side of the circuit board. These mounting surfaces on the front side of the circuit board are preferably designed as cooling surfaces, in particular as metallic cooling surfaces, each of which is preferably thermally connected to the back side of the circuit board via a plurality of thermal vias.

It is a preferred measure that additional thermal connecting elements are provided, each of which extends from the front side to the back side of the circuit board, wherein each additional thermal connecting element is arranged outside the separate mounting surfaces. Thus, the thermal connecting elements also comprise such elements which are not arranged under the mounting surfaces for the circuit breakers, but in other areas of the circuit board. In this way, heat can also be specifically dissipated from areas on the front side of the circuit board where no circuit breakers are arranged.

It is a further preferred measure that for each mounting surface a contact pad is provided in each case on the back side of the circuit board, which thermally couples all thermal connecting elements belonging to this mounting surface to each other. This means that all thermal connecting elements belonging to the same mounting surface end on the back side of the circuit board on the contact pad, which thus thermally couples all these thermal connecting elements on the back side of the circuit board to each other. By these contact pads, the thermal connection to the housing of the magnetic levitation device can be further improved, because the heat is transferred to the housing over a large area by the contact pads.

Furthermore, it is a preferred measure that a heat conducting layer is arranged between the web and the back side of the circuit board, with which heat can be transferred from the circuit board to the housing.

The heat conducting layer is preferably designed as a film, which is attached to the back side of the circuit board. The film consists of a thermally conductive material. This film can be mounted or soldered to the back side of the circuit board. The heat conducting layer is able to transfer the heat to the housing over a wide area and thus reduce the thermal transition resistance.

Each heat conducting layer designed as a film is preferably made of a thermally well conductive and easily deformable, in particular ductile material, so that the films can also compensate for small unevennesses and mechanical tolerances.

Particularly preferably, the heat conducting layer is made of a metallic material, such as copper or silver. Each heat conducting layer is designed as a copper film, for example. Copper films have the advantage that they are easy to solder. To further improve solderability, the copper films can also be coated with a precious metal (with gold, for example).

It is another possibility to use a lacquer for the heat conducting layer. Here, such lacquers that contain a high proportion of metal particles are preferred. These lacquers are then applied to the contact surfaces to generate the heat conducting layer. The resulting heat conducting layer is also relatively easy to deform and also enables a very good thermal connection.

According to a preferred embodiment, the control housing of the housing is designed with an interior space having a substantially rectangular or square cross-sectional area perpendicular to the axial direction. This is preferred because the control housing is thus particularly well suited for receiving the preferably rectangular or square designed circuit board of the control device. A rectangular or square design of the circuit board is much easier in particular in terms of manufacturing than, for example, a round design.

Furthermore, it is preferred that the stator housing of the housing is designed with an interior space having a substantially round cross-sectional area perpendicular to the axial direction A. This is preferred because the stator housing is thus particularly well suited for receiving the coil cores of the stator, which are preferably arranged on a circular line.

In a preferred embodiment, a housing cover is arranged at one axial end of the magnetic levitation device, which cover closes the control housing. Particularly preferably, the housing cover is designed to hermetically seal the control housing.

Furthermore, it is preferred that the stator comprises a containment can which forms one axial end of the stator, wherein the containment can has the cup-shaped recess. The rotor to be levitated can then be inserted into the cup-shaped recess of the containment can.

Preferably, the separating wall comprises an inner cup which is substantially designed in a cylindrical manner, and which is arranged radially inwardly with respect to the windings in the interior space surrounded by the windings. The inner cup is advantageous in order to better dissipate the heat generated in the stator in the operating state, e.g. the heat generated by copper losses and iron losses.

The housing comprises the stator housing and the control housing, which are preferably arranged adjacent to each other with respect to the axial direction, wherein the stator housing is designed for receiving the coil cores with the concentrated windings arranged thereon, and the control housing is designed for receiving the control unit for controlling and supplying the windings with electrical energy for generating electromagnetic fields.

Preferably, the housing is designed in such a way that the coil cores with the concentrated windings arranged thereon can be inserted into the stator housing in a first installation direction in the axial direction, and the control unit can be inserted into the control housing in a second installation direction, wherein the first installation direction is directed in the opposite direction to the second installation direction. The housing preferably has two areas separated from each other, one of which forms the stator housing and the other the control housing. These two areas are separated from each other by the separating wall. The separating wall has passages, e.g. for electrical connections. The housing is preferably designed in one piece with respect to the circumferential direction.

According to a particularly preferred embodiment, the stator is designed to generate a torque with which the rotor can be driven magnetically without contact for rotation about the axial direction.

Further advantageous measures and embodiments of the disclosure are apparent from the dependent claims.

### BRIEF DESCRIPTION OF THE DRAWINGS

In the following, the disclosure will be explained in more detail with reference to embodiments and with reference to the drawings.

FIG. 1 is a sectional representation of an embodiment of a magnetic levitation device according to the disclosure,

FIG. 2 is a perspective representation of the embodiment from FIG. 1 in an exploded view,

FIG. 3 is a perspective representation of the stator and the holding device,

FIG. 4: a perspective exploded view of the coil cores, the windings, and the holding device,

FIG. 5 is a sectional representation of the containment can of the stator,

FIG. 6 is a perspective representation of the control housing and the circuit board of the control device,

FIG. 7 is a schematic representation of thermal connecting elements,

FIG. 8 is a plan view onto the control housing,

FIG. 9 is a plan view onto the back side of an embodiment of a circuit board,

FIG. 10 is a plan view onto the front side of an embodiment of a circuit board,

FIG. 11 is a plan view onto the back side of variant for the circuit board,

FIG. 12 is a schematic sectional representation of the circuit board from FIG. 11, and

FIG. 13 is a perspective representation of a heat conducting layer.

### DETAILED DESCRIPTION

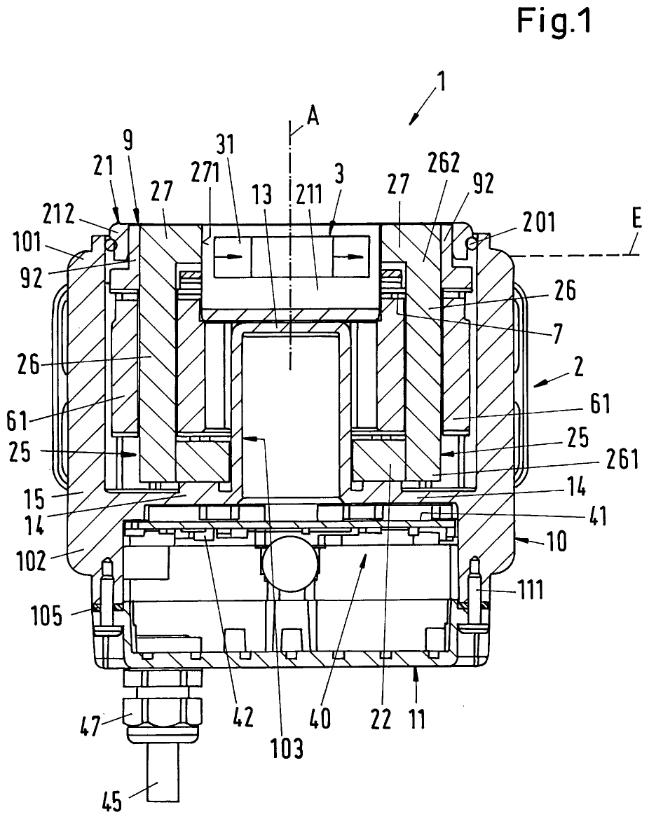

FIG. 1 shows a sectional representation of an embodiment of a magnetic levitation device according to the disclosure, which is designated in its entirety by the reference sign 1. The magnetic levitation device 1 is designed for the contactless magnetic levitation of a rotor 3, which comprises a disk-shaped or ring-shaped magnetically effective core 31.

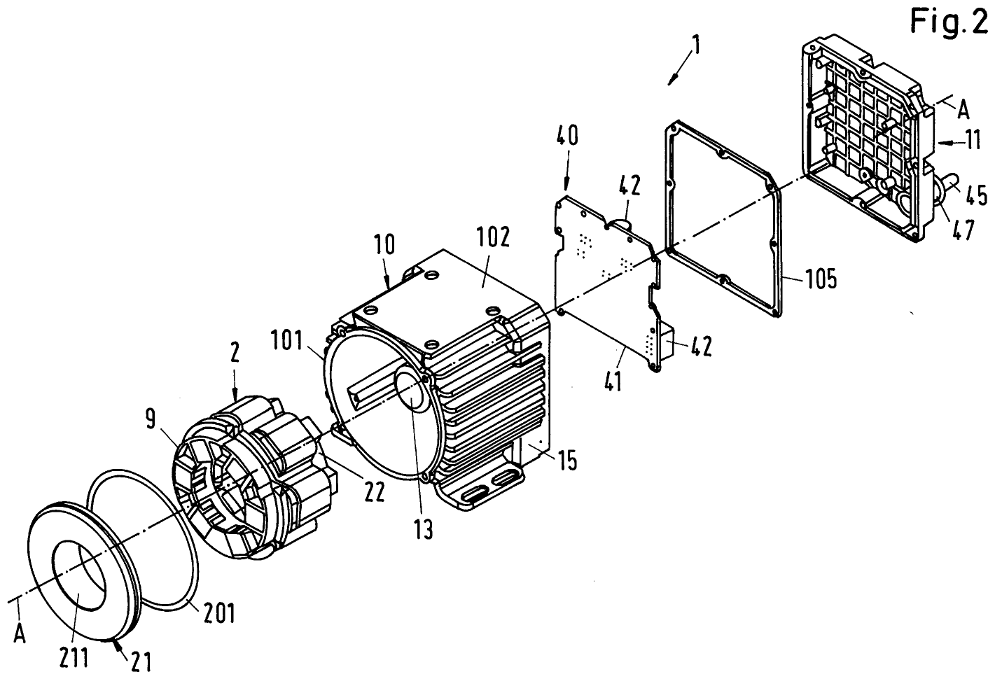

For better understanding, FIG. 2 still shows a perspective representation of the embodiment from FIG. 1 in a perspective exploded view, whereby the rotor 3 is not represented in FIG. 2. The magnetic levitation device 1 is designed according to the temple construction and comprises a stator 2, which has a plurality of coil cores 25—here six coil cores 25—each of which comprises a longitudinal leg 26, which extends from a first end 261 in an axial direction A to a second end 262, and a transverse leg 27 arranged perpendicular to the longitudinal leg 26, which extends in a radial direction which is perpendicular to the axial direction A. Each transverse leg 27 is delimited with respect to the radial direction by an end face 271, which forms the pole of the associated coil core 25.

At least one concentrated winding 61, in this embodiment exactly one, is provided at each longitudinal leg 26, which surrounds the respective longitudinal leg 26.

The magnetic levitation device 1 comprises a housing 10 in which the coil cores 25 are arranged.

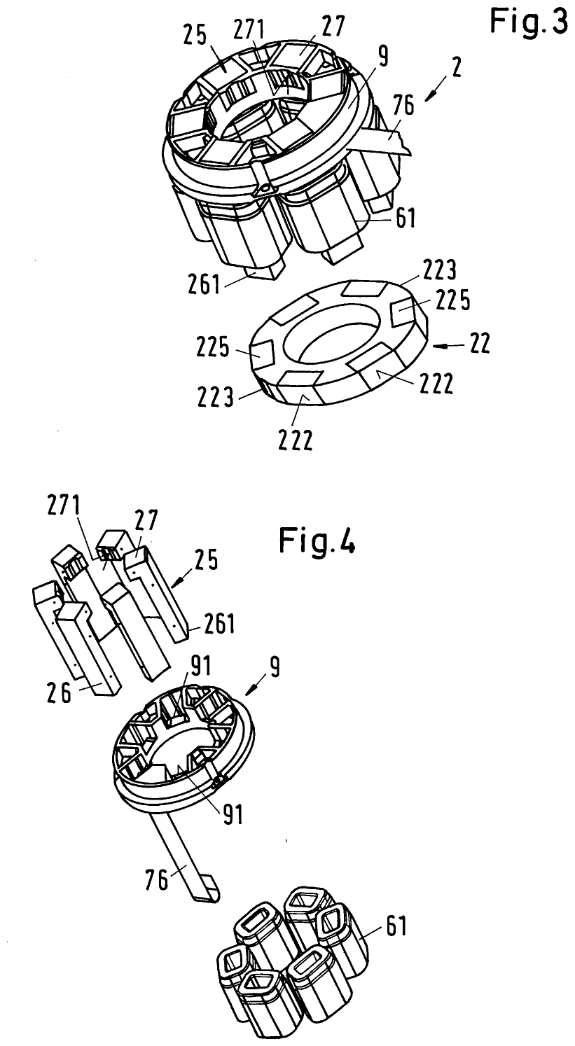

For better understanding, FIG. 3 and FIG. 4 show further representations of the stator 2 of the embodiment of the magnetic levitation device 1, whereby the housing 10 is not represented. FIG. 3 shows a perspective representation of the stator 2 and a holding device 9 for the coil cores 25. Furthermore, a back iron 22 is represented in FIG. 3, which connects all first ends 261 of the longitudinal legs 26 to one another—i.e. the lower ends 261 according to the representation (FIG. 1)—and serves to conduct the magnetic flux. The back iron 22 is preferably designed in a ring-shaped manner. FIG. 4 shows a perspective exploded view of the coil cores 25 with the concentrated windings 61 arranged thereon and the holding device 9.

The housing 10 is preferably made of a metallic material, for example aluminum or stainless steel. For better chemical resistance, the housing 10 can be provided with a coating, preferably with a plastic coating made of a highly chemically resistant plastic. Examples of such plastics are PTFE (polytetrafluoroethylene), PFA (perfluoroalkoxy polymers), ECTFE (ethylene chlorotrifluoroethylene), ETFE (ethylene tetrafluoroethylene), epoxy resin (polyepoxy), PPA (polyphthalamide), PE (polyethylene). Depending on the intended application, the housing 10 can also be made of titanium or chrome steel.

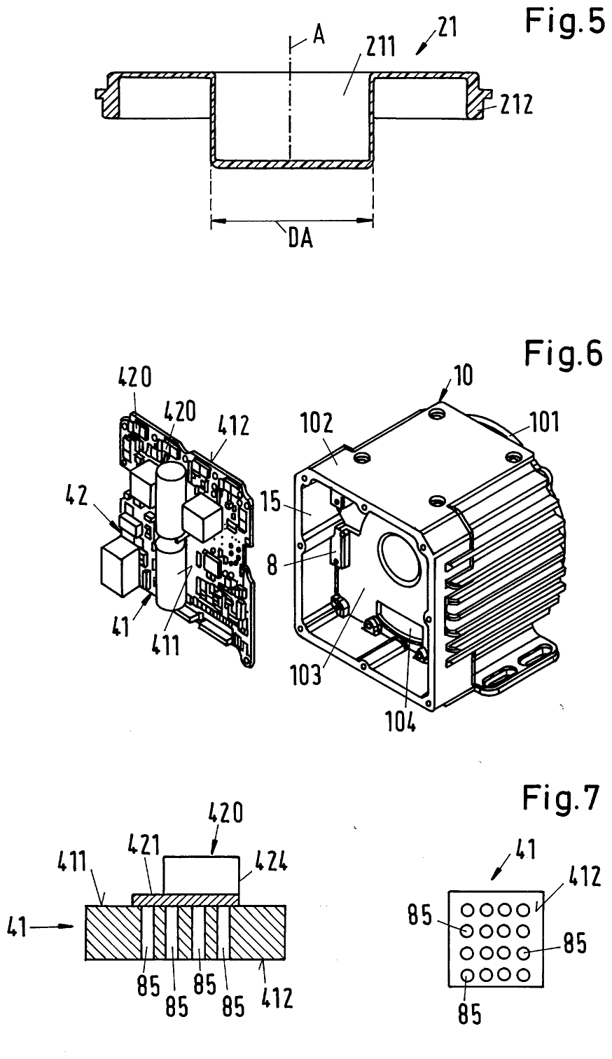

The stator 2 further comprises a containment can 21 with a cup-shaped recess 211 (see also FIG. 5), into which the rotor 3 to be levitated can be inserted (see FIG. 1). The containment can 21 forms one of the two axial ends of the stator 2 or the magnetic levitation device 1, according to the representation in FIG. 1 the upper axial end of the stator 2. A housing cover 11, which closes the housing 10, is arranged at the other axial end of the magnetic levitation device 1.

The containment can 21 is firmly connected to the housing 10, for example by a form-locking connection and/or by an elastic seal 201. Preferably, the containment can 21 is connected to the housing 10 in a hermetically sealed manner. The housing cover 11 is firmly connected to the housing 10, for example by screws 111 (FIG. 1), whereby a sealing element 105 is optionally arranged between the housing cover 11 and the housing 10. The sealing element 105 can in particular be designed as a flat sealing. Preferably, the housing cover 11 is connected to the housing 10 in a hermetically sealed manner.

Particularly preferably, the housing 10 together with the containment can 21 and the housing cover 11 forms a hermetically sealed housing in which the other components of the stator 2 are encapsulated in a hermetically sealed manner. The housing 10 is preferably filled with a potting compound with good thermal conductivity, for example with an epoxy resin, so that the components arranged inside the housing 10 are surrounded by the potting compound. In this way, the general thermal resistance is reduced, and vibrations are dampened.

Preferably, the housing cover 11 is made of a plastic. A chemically resistant plastic such as polypropylene is preferred, particularly for applications in chemically aggressive environments.

The transverse legs 27 of the coil cores 25 are arranged in the containment can 21 in such a way that the end faces 271 of the transverse legs 27 are arranged around the cup-shaped recess 211.

The coil cores 25 of the stator 2 are arranged equidistantly on a circular line, so that the end faces 271 surround the magnetically effective core 31 of the rotor 3 when the rotor 3 is inserted into the cup-shaped recess 211. Exactly one concentrated winding 61 is provided in each case at each longitudinal leg 26, which surrounds the longitudinal leg 26.

In other embodiments, more than one concentrated winding can also be arranged at the longitudinal legs 26. For example, there are embodiments in which exactly two concentrated windings are provided in each case at each of the longitudinal legs 26, each of which surrounds the respective longitudinal leg 26, wherein the two windings arranged on the same longitudinal leg 26 are arranged adjacent to each other with respect to the axial direction A.

The concentrated windings 61 serve to generate electromagnetic fields with which the rotor 3 can be magnetically levitated without contact in the cup-shaped recess 211 of the containment can 21.

Furthermore, a control unit (controller) 40 is provided for controlling and supplying the windings 61 with electrical energy. The control unit 40 comprises in particular the power electronics, which feed the required currents into the windings 61. The control unit 40 is represented in FIG. 1 and FIG. 2. Particularly preferably, the control unit 40 is also arranged inside the housing 10, for example according to the representation (FIG. 1) below the first ends 261 of the longitudinal legs 26 of the coil cores 25. Optionally, the control unit 40 is also surrounded with a thermal potting compound or coupled to the housing 10 and the back iron 22 and/or the coil cores 25 of the stator 2. The control unit 40 comprises a circuit board 41 on which various electronic components 42 are arranged.

As can be recognized in particular in FIG. 1 and FIG. 2, the housing 10 preferably comprises two areas which are separate from each other and arranged adjacent to each other with respect to the axial direction A, one of which forms a stator housing 101 and the other a control housing 102. The stator housing 101 of the housing 10 is designed for receiving the coil cores 25 with the windings 61 arranged thereon, and the control housing 102 is designed for receiving the control unit 40. The stator housing 101 and the control housing 102 are separated from each other by a separating wall 103, wherein lead-throughs or openings 104 (see e.g. FIG. 6) are provided in the separating wall 103, through which connecting lines, for example electrical connections, can be passed from the control housing 102 into the stator housing 101.

According to a preferred measure, the separating wall 103 comprises an inner cup 13 which is substantially designed in a cylindrical manner, and which is arranged radially inwards with respect to the windings 61 in the interior space surrounded by the windings 61. The inner cup 13 is connected to an outer wall 15 of the housing 10 via a flange-like projection 14 of the separating wall 103. The outer wall 15 forms the radially outer boundary of the housing 10. Particularly preferably, the separating wall 103, which comprises the inner cup 13 and the flange-like projection 14 is an integral part of the housing 10. The outer wall 15 and the separating wall 103 are designed in one piece as a whole and form the preferably one-piece housing 10.

The separating wall 103 with the inner cup 13 and the flange-like projection 14 separate the area of the housing 10 which forms the stator housing 101 from the area that forms the control housing 102.

The inner cup 13 of the separating wall 103 connected to the flange-like projection 14 extends from the radially inward edge of the flange-like projection 14 in the axial direction A and is arranged radially inwardly with respect to the windings 61 and the back iron 22 in the interior space surrounded by the windings 61, as can be recognized in particular in FIG. 1. With respect to the radial direction, the inner cup 13 is arranged adjacent to the longitudinal legs 26 of the coil cores 25 or the windings 61 arranged thereon, so that the inner cup 13 can absorb and dissipate the heat generated by the windings 61 and the coil cores 25 particularly well. With respect to the axial direction A, the inner cup 13 extends approximately up to the cup-shaped recess 211 of the containment can 21.

As can be recognized in particular in FIG. 2, the stator housing 101 of the housing 10 is designed with an interior space which has a substantially circular or ring-shaped cross-sectional area perpendicular to the axial direction A. This is preferred because the stator housing 101 can thus receive the ring-shaped back iron 22 with the coil cores 25 arranged around the back iron 22 particularly well. The control housing 102 of the housing 10 is designed with an interior space which has a substantially rectangular or square cross-sectional area perpendicular to the axial direction A. This is preferred because the control housing 102 is thus particularly well suited to receive the preferably rectangularly or squarely designed circuit board 41 of the control unit 40. Particularly with respect to manufacturing, a rectangular or square design of the circuit board 41 is much simpler than, for example, a round design.

Due to this embodiment of the stator housing 101 and the control housing 102, the axial end of the stator 2, at which the containment can 21 closes the housing 10, has a substantially round cross-section, so that the containment can 21 has a round or circular ring-shaped design. In contrast, the axial end of the stator 2, at which the housing cover 11 closes the housing 10, has a substantially rectangular or square cross-section, so that the housing cover 11 has a rectangular or square design.

With an exemplary character, some components of the control unit 40 are represented in FIG. 1. For example, the control unit 40 comprises the circuit board 41 on which the electronic components 42 are provided, e.g. the power electronics for controlling the windings 61. This will be explained in more detail below. For example, the circuit board 41 can further contain evaluation electronics for evaluating the signals from sensors, e.g. magnetic field sensors, or can serve as a communication interface. The circuit board 41 is preferably designed as an electronic print or PCB (printed circuit board). Furthermore, a connection cable 45 is provided, which is connected to the circuit board 41 via a cable connection (not represented) or a plug. The connection cable 45 leads out of the housing 10 and serves, for example, to supply power to the magnetic levitation device 1. The connection cable 45 is led out of the housing 10 by a sealingly designed cable bushing 47. Preferably, the cable bushing 47 is designed in a hermetically sealing manner.

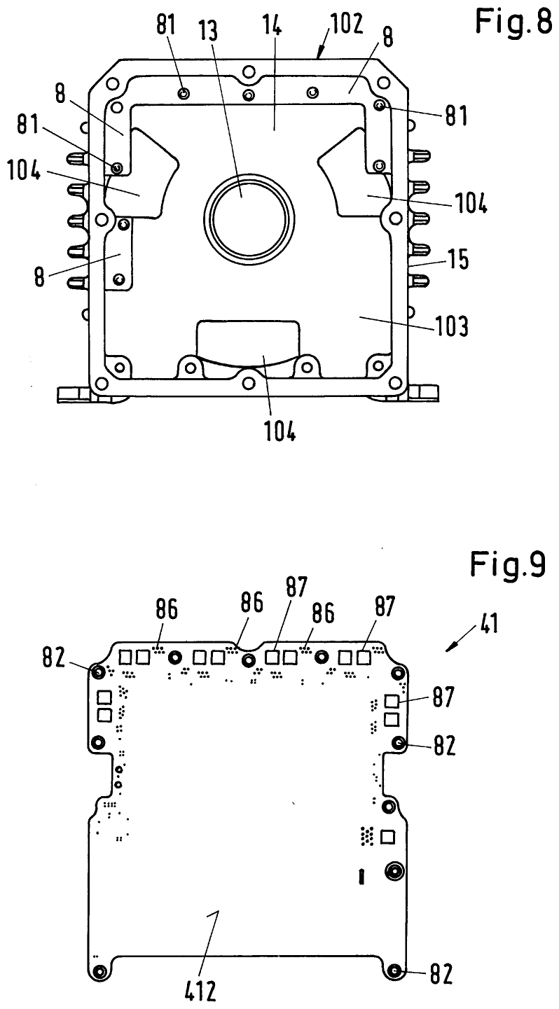

The circuit board 41 of the control unit 40 is connected to the windings 61 via connecting lines (not represented), for example cables, in order to control them and supply them with energy. For this purpose, the feedthroughs or openings 104 (FIG. 8) are provided in the separating wall 103 through which the connecting lines are passed. Such feedthroughs can, for example, be arranged in the flange-like projection 14 or in the inner cup 13.

The circuit board 41 is preferably arranged on the flange-like projection 14, as will be explained in more detail below. In this way, it is possible in a particularly efficient way to dissipate the heat generated in the control unit 40 via the housing 10.

The interior space of the inner cup 13, i.e. the space enclosed by the inner cup 13, can be used for further electronic components, electronics boards or plugs or connections. These are not represented in FIG. 1 for reasons of a better overview.

According to an especially preferred embodiment, the stator 2 is designed in such a way that, in addition to the contactless magnetic levitation of the rotor 3, it can also exert a torque on the rotor 3 or the magnetically effective core 31 of the rotor 3, which drives the rotor 3 for a rotation about a desired axis of rotation. Here, the desired axis of rotation designates that axis about which the rotor 3 rotates in the operating state when the rotor 3 is in a centered and non-tilted position with respect to the stator 2, as is represented in FIG. 1. This desired axis of rotation extends in the axial direction A, i.e. in this preferred embodiment, the rotor 3 arranged in the containment can 21 of the stator 2 can be driven for rotation about the axial direction A. Normally, the desired axis of rotation coincides with the center axis of the stator 2, which extends in the axial direction A.

In this embodiment, the concentrated windings 61 thus generate electromagnetic rotating fields with which the rotor 3 can be both magnetically levitated without contact with respect to the stator 2 and can also be driven without contact for rotation about the axial direction A.

It is understood that the number of six coil cores 25, although preferred, is only to be understood as an example. Of course, such embodiments are also possible in which the stator 2 has fewer than six, e.g. five or four or three coil cores 25, or such embodiments in which the stator 2 has more than six, e.g. seven or eight or nine coil cores 25 or any larger number of coil cores 25.

The rotor 3 comprises the magnetically effective core 31, which is designed in a ring-shaped or disk-shaped manner. According to the representation in FIG. 1, the magnetically effective core 31 is designed as a ring and defines a magnetic center plane. Alternatively, the magnetically effective core 31 can also be designed as a disk. Normally, in the case of a disk-shaped or ring-shaped magnetically effective core 31, the magnetic center plane is the geometric center plane of the magnetically effective core 31 of the rotor 3, which lies perpendicular to the axial direction A. In the operating state, the magnetically effective core 31 is levitated in a radial plane E, which stands perpendicular on the axial direction A. The radial plane is indicated in FIG. 1 by the line E, which stands perpendicular on the axial direction A. Thus, the radial plane E is that plane which stands perpendicular on the axial direction A and contains the line E.

The radial plane E is that plane in which the magnetically effective core 31 of the rotor 3 is actively magnetically levitated between the end faces 271 in the stator 2 in the operating state. If the rotor 3 is not tilted and is not deflected in the axial direction A, the magnetic center plane lies in the radial plane E. The radial plane E defines the x-y plane of a Cartesian coordinate system whose z-axis runs in axial direction A.

The radial position of the magnetically effective core 31 or the rotor 3 refers to the position of the rotor 3 in the radial plane E.

Since it is sufficient for the understanding of the disclosure, only the magnetically effective core 31 is represented from the rotor 3 in the drawing in FIG. 1. It is understood that the rotor 3 can of course also comprise further components such as jackets or encapsulations, which are preferably made of a plastic, or of a metal or of a metal alloy or of a ceramic or a ceramic material. Furthermore, the rotor 3 can also comprise vanes for mixing, stirring or pumping fluids or other components.

When the rotor 3 is inserted into the cup-shaped recess 211 of the containment can 21, the rotor 3 and in particular the magnetically effective core 31 of the rotor 3 is surrounded by the radially outwardly arranged end faces 271 of the transverse legs 27 of the coil cores 25 of the stator 2. Thus, the transverse legs 27 form a plurality of pronounced stator poles-in this case six stator poles. The transverse legs 27 are arranged at the upper ends of the longitudinal legs 26 and in the radial plane E. Each transverse leg 27 extends in the radial direction towards the rotor 3.

When the magnetically effective core 31 of the rotor 3 is in its desired position during operation, the magnetically effective core 31 is centered between the end faces 271 of the transverse legs 27 so that the transverse legs 27 arranged in the radial plane E also lie in the magnetic center plane. According to the representation, the concentrated windings 61 are arranged below the radial plane E and are aligned such that their coil axes run in the axial direction A.

All first ends 261 of the longitudinal legs 26—i.e., the lower ends 261 according to the representation (FIG. 1)—are connected to each other by the back iron 22 (see also FIG. 3). The back iron 22 is preferably designed in a ring-shaped manner. Here, such embodiments are possible (see FIG. 1, for example) in which the back iron 22 extends radially inwardly along all first ends 261 of the longitudinal legs 26.

In order to generate the electromagnetic fields required for the magnetic levitation of the rotor 3 and optionally for the generation of a torque on the rotor 3, the longitudinal legs 26 of the coil cores 25 carry the windings designed as concentrated windings 61.

In the operating state, those electromagnetic rotating fields are generated with these concentrated windings 61, with which an arbitrarily adjustable transverse force in the radial direction can be exerted on the rotor 3, so that the radial position of the rotor 3, i.e. its position in the radial plane E perpendicular to the axial direction A, can be actively controlled or regulated. Optionally, a torque is additionally effected on the rotor 3 with these electromagnetic rotating fields.

The “magnetically effective core 31” of the rotor 3 refers to that region of the rotor 3 which magnetically interacts with the stator 2 for the generation of magnetic levitation forces and optionally for torque generation.

As already mentioned, the magnetically effective core 31 is designed in a ring-shaped manner in this embodiment. Furthermore, the magnetically effective core 31 is designed in a permanent magnetic manner. For this purpose, the magnetically effective core 31 can comprise at least one permanent magnet, but also several permanent magnets, or—as in the embodiment described here—consist entirely of a permanent magnetic material, so that the magnetically effective core 31 is the permanent magnet. For example, the magnetically effective core 31 is magnetized in the radial direction.

Such embodiments are also possible in which the magnetically effective core 31 is designed in a permanent magnet-free manner, i.e., without permanent magnets. The rotor 3 is then designed, for example, as a reluctance rotor. Then, the magnetically effective core 31 of the rotor 3 is made of a soft magnetic material, for example. Suitable soft magnetic materials for the magnetically effective core 31 are, for example, ferromagnetic or ferrimagnetic materials, i.e., in particular iron, nickel-iron, cobalt-iron, silicon iron, mu-metal.

Furthermore, embodiments are possible in which the magnetically effective core 31 of the rotor 3 comprises both ferromagnetic materials and permanent magnetic materials. For example, permanent magnets can be placed or inserted into a ferromagnetic base body. Such embodiments are advantageous, for example, if one wishes to reduce the costs of large rotors by saving permanent magnetic material.

Embodiments are also possible in which the rotor is designed according to the principle of a cage rotor.

Both the ring-shaped back iron 22 and the coil cores 25 of the stator 2 are each made of a soft magnetic material because they serve as flux conducting elements to conduct the magnetic flux.

Suitable soft magnetic materials for the coil cores 25 and the back iron 22 are, for example, ferromagnetic or ferrimagnetic materials, i.e., in particular iron, nickel-iron, cobalt-iron, silicon iron or mu-metal. In this case, for the stator 2, a design as a stator sheet stack is preferred, in which the coil cores 25 and the back iron 22 are designed in sheet metal, i.e., they include several thin sheet metal elements, which are stacked.

Furthermore, it is possible that the coil cores 25 and the back iron 22 are made of pressed and subsequently sintered grains of the aforementioned materials. The metallic grains are preferably embedded in a plastic matrix so that they are at least partially insulated from one another, whereby eddy current losses can be minimized. Thus, soft magnetic composites including electrically insulated and compressed metal particles are also suitable for the stator. In particular, these soft magnetic composites, which are also designated as SMC (Soft Magnetic Composites), can consist of iron powder particles which are coated with an electrically insulating layer. These SMC are then formed into the desired shape by powder metallurgy processes.

During operation of the magnetic levitation device 1, the magnetically effective core 31 of the rotor 3 interacts with the stator 2 in such a way that the rotor 3 can be magnetically levitated without contact with respect to the stator 2 and preferably can also be magnetically set in rotation without contact about the axial direction A. In this case, it is particularly advantageous that the same windings 61, with which the magnetic levitation of the rotor 3 is effected, also serve to generate a torque on the rotor 3. Preferably, three degrees of freedom of the rotor 3 can then be actively regulated, namely its position in the radial plane E and its rotation. With respect to its axial deflection from the radial plane E in the axial direction A, the magnetically effective core 31 of the rotor 3 is passively magnetically stabilized by reluctance forces, i.e., it cannot be controlled. The magnetically effective core 31 of the rotor 3 is also passively magnetically stabilized with respect to the remaining two degrees of freedom, namely tilting with respect to the radial plane E perpendicular to the desired axis of rotation. By the interaction of the magnetically effective core 31 with the coil cores 25, the rotor 3 is thus passively magnetically levitated or passively magnetically stabilized in the axial direction A and against tilting (a total of three degrees of freedom) and actively magnetically levitated in the radial plane (two degrees of freedom).

As is generally the case, an active magnetic levitation is also referred to in the framework of this application as one which can be actively controlled or regulated, for example by the electromagnetic fields generated by the concentrated windings 61. A passive magnetic levitation or a passive magnetic stabilization is one that cannot be controlled or regulated. The passive magnetic levitation or stabilization is based, for example, on reluctance forces, which bring the rotor 3 back again to its desired position when it is deflected from its desired position, i.e., for example, when it is displaced or deflected in the axial direction A or when it is tilted.

In the magnetic levitation device 1, in contrast to classic magnetic bearings, the magnetic levitation-and optionally the generation of a torque acting on the rotor-is realized by electromagnetic rotating fields. For the combined generation of the magnetic levitation forces and a torque for rotating the rotor 3 about the axial direction A, it is possible on the one hand—as shown in FIG. 1—to arrange exactly one concentrated winding 61 at each longitudinal leg 26.

On the other hand, embodiments are also possible in which two different winding systems are provided for the combined generation of the magnetic levitation forces and a torque for rotating the rotor 3. For this purpose, for example, exactly two concentrated windings are arranged in each case at each longitudinal leg, which are arranged adjacent to each other with respect to the axial direction A. One of these two windings belongs to the first of the two winding systems and the other to the second of the two winding systems.

In the embodiment represented in FIG. 1 with exactly one concentrated winding 61 at each coil core 25, the values for the current required for the levitation and the current required for the generation of the torque determined in each case, for example, in the control unit 40 are added or superimposed by calculation—e.g., with the aid of software. Then, the resulting total current is impressed into the respective concentrated winding 61.

For better understanding, the back iron 22 is represented separately from the coil cores 25 in FIG. 3. The back iron 22 is substantially designed in a ring-shaped manner and extends radially inwards along the first ends 261 of the longitudinal legs 26 in the assembled state (see also FIG. 1). Preferably, the back iron 22 is designed in sheet metal. In the sheet-metal embodiment, the back iron 22 is made of a plurality of thin elements which are stacked parallel to each other in the axial direction. All elements are identically designed, in this case substantially ring-shaped and also with the same thickness in each case.

On its radially outer circumferential surface, the back iron 22 has a plurality of flattenings 222, which are designed in a planar manner, i.e. not curved. In the assembled state of the stator 2, a first end 261 of one of the longitudinal legs 26, which preferably have a rectangular profile, rests against each of these flattenings 222 in each case. Due to the planar design of the flattenings 222, a large contact surface between the back iron 22 and the longitudinal legs 26 of the coil cores 25 is ensured, resulting in a particularly good conducting of the magnetic flux or a very low magnetic resistance at the transition between the back iron 22 and the longitudinal legs 26. The flattenings can also be arranged at separate segments 225, wherein the separate segments 225 are arranged in grooves of the back iron 22. The grooves are dimensioned such that the separate segments 225 are flush with the rest of the back iron 22.

Preferably, the number of flattenings 222 is the same as the number of the coil cores 25, i.e. six flattenings 222 are provided here, which are distributed equidistantly along the outer circumference of the back iron 22.

Furthermore, one or more venting holes or venting recesses 223 can be provided at the back iron 22, which extend completely through the back iron 22 with respect to the axial direction A. Air can escape through the venting recesses 223, for example when filling the housing 20 with a thermally conductive potting compound.

In order to determine the current position of the rotor 3 in the cup-shaped recess 211, the magnetic levitation device 1 preferably comprises a plurality of magnetic field sensors (not represented), which are arranged around the cup-shaped recess 211 in the assembled state of the magnetic levitation device 1. The magnetic field sensors are sensors with which a magnetic field can be measured. With the aid of the magnetic field sensors, the current position of the rotor 3 in the cup-shaped recess 211 of the containment can 21 or in the radial plane E can be determined in a manner known per se.

Preferably, the magnetic field sensors are arranged on a sensor board 7 and are signal-connected to it via electrical connections, so that all magnetic field sensors can be controlled via the sensor board 7 and the signals measured by the magnetic field sensors can be received and processed via the sensor board 7 or, for example, transmitted to the control unit 40.

The sensor board 7 is arranged with respect to the axial direction A between the windings 61 on the one hand and the transverse legs 27 on the other hand. The holding device 9 is designed for receiving the sensor board 7.

The sensor board 7 further comprises an electrical connecting element 76, which connects the sensor board 7 to the control unit 40, so that the control unit 40 and the sensor board 7 can exchange electrical voltages or currents via the electrical connecting element 76. The electrical connecting element 76 is preferably designed as a flexprint. Of course, the electrical connecting element 76 can also be designed in a different manner, for example as a cable, a cable bundle, or a flat ribbon cable.

In a sectional representation, FIG. 5 shows the containment can 21 of the stator 2 of the embodiment of the magnetic levitation device 1, wherein the section is made in the axial direction A.

The containment can 21 with the cup-shaped recess 211 is preferably designed in one piece. The cup-shaped recess has an outer diameter DA that is dimensioned such that the rotor 3 to be levitated can be inserted into the cup-shaped recess 211. The containment can 21 is preferably made of a plastic and in particular preferably of a plastic that can be processed by injection molding. Thus, the containment can 21 is preferably designed as an injection molded part. Suitable plastics for manufacturing the containment can 21 are, for example, acrylonitrile-butadiene-styrene (ABS), polyamide (nylon, PA), polypropylene (PP), polytetrafluoroethylene (PTFE), perfluoroalkoxy alkanes (PFA), polyvinyl chloride (PVC), polybutylene terephthalate (PBT), polyimide (PI), polyether ketone, polysuccinimide (PSI), polyphthalamide (PPA) or polyether ether ketone (PEEK).

The containment can 21 comprises the cup-shaped recess 211, into which the rotor 3 can be inserted, and a radially outer edge 212, which, in the assembled state, embraces the axial edge area 92 of the holding device 9.

The holding device 9 is substantially designed in a plate-shaped and ring-shaped manner and comprises several notches 91 (FIG. 4) for receiving the transverse legs 27 of the coil cores 25. Exactly one notch 91 is provided for each transverse leg 27, so that the number of notches 91 is equal to the number of coil cores 25. The holding device 9 is inserted into the containment can 21 (see FIG. 1) and extends from the bottom of the containment can 21 in the axial direction A to a lower edge according to the representation (FIG. 1), which is arranged above the windings 61 with respect to the axial direction A according to the representation.

The holding device 9 is designed in a ring-shaped manner in such a way that it can be arranged around the cup-shaped recess 211 of the containment can 21, i.e. the cup-shaped recess 211 is enclosed radially on the outside by the holding device 9.

The holding device 9 is preferably made of a plastic and in particular preferably of a plastic that can be processed by injection molding. The holding device 9 is thus preferably designed as an injection-molded part. Suitable plastics for the manufacture of the holding device 9 are, for example, acrylonitrile-butadiene-styrene (ABS), polyamide (nylon, PA), polypropylene (PP) or fiber-filled polypropylene.

The holding device 9 serves both as a holder for the sensor board 7 with the magnetic field sensors and as a guide and holder for the coil cores 25.

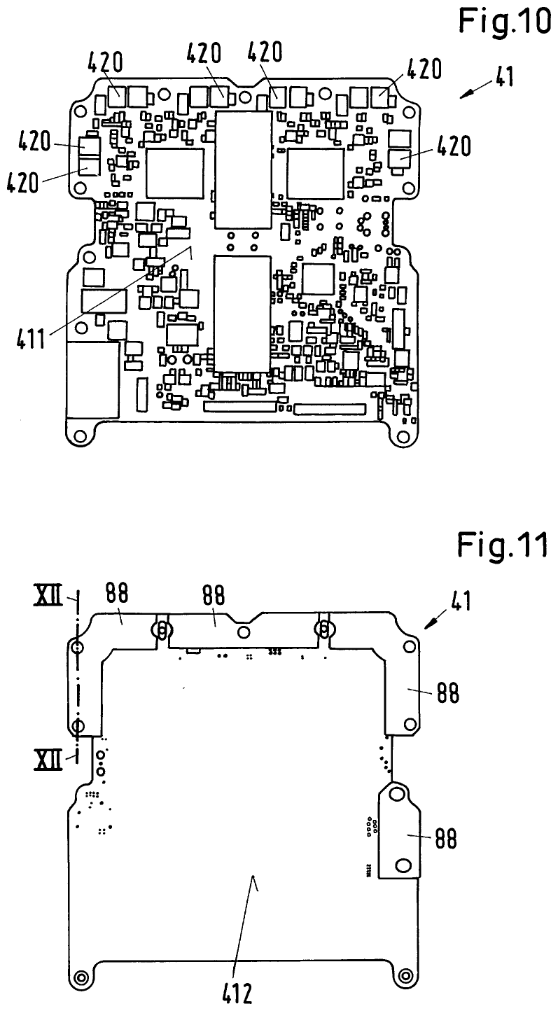

FIG. 6 shows a perspective representation of the control housing 102 and the circuit board 41 of the control unit 40. The circuit board 41 has a front side 411 and a back side 412. The electronic components 42, which are necessary for controlling and supplying the windings 61 with electrical energy, are arranged on the front side of the circuit board 41 of the control unit 40. In particular, these are circuit breakers 420 (see also FIG. 10) for controlling the windings 61, with which the current supplied to the windings 61 is switched. The electronic components 42 further comprise regulation and control components for controlling the contactless magnetic levitation and optionally the contactless magnetic drive, which are known per se and are therefore not explained in more detail here.

The circuit breakers 420 typically comprise transistors, preferably MOSFETs, with which half bridges or full bridges are realized that control the windings 61 of the stator 2. Typically, one or more such half-bridge or full-bridge circuits are arranged in a chip housing 424 (FIG. 7) of the circuit breaker 420, wherein drivers can optionally also be provided in the chip housing 424. The chip housing 424 of the circuit breaker 420 is then attached to the front side 411 of the circuit board 41 by a so-called Die Attach Paddle (DAP). Several connection pins are provided (not shown in detail) at the chip housing 424 of the circuit breaker 420, via which the electronic components of the circuit breaker 420, i.e., for example the transistors, can be electrically connected to conductor tracks or electrical connectors on the circuit board 41. The chip housings 424 of the circuit breakers 420 are attached to the circuit board 41 by adhesives or by a soldered connection, for example.

For better understanding, FIG. 8 shows a plan view onto the control housing 102. FIG. 9 shows a plan view onto the back side 412 of the circuit board 41 and FIG. 10 shows a plan view onto the front side 411 of the circuit board 41.

As can be clearly recognized in particular in FIG. 6 and FIG. 8, a plurality of webs 8 are provided on the separating wall 103, which delimits the control housing 102, and adjacent to the outer wall 15 of the housing 10, which webs project into the control housing 102. Preferably, the webs 8 are an integral part of the separating wall 103 and the outer wall 15. Particularly preferably, the housing 10, i.e. in particular the outer wall 15, the separating wall 103 and the webs 8 form a structural unit, which is preferably made of a metallic material, for example aluminum or a stainless steel.

The webs 8 are arranged where the separating wall 103 adjoins the outer wall 15. The webs 8 serve to support the circuit board 41. The circuit board 41 is placed with its back side 412 on the webs 8 and attached to the webs 8, for example by a plurality of screws which reach through screw holes 82 (FIG. 9) in the circuit board 41 and engage in threaded holes 81 which are arranged on the webs 8.

The webs 8 thus serve as a support on which the back side 412 of the circuit board 41 is supported. “Support” or “to rest on” is thus to be understood as meaning that the webs 8 support the circuit board 41, but this is not intended to mean that the back side 412 of the circuit board 41 must be in direct physical contact with the webs 8. Of course, embodiments are possible in which the back side 412 is in direct physical contact with the webs 8. However, embodiments are also possible in which the webs 8 are only partially or not at all in direct physical contact with the back side of the circuit board 41, because contact pads 87 or heat conducting layers 88 can be arranged between the back side 412 of the circuit board 41 and the webs 8, for example. This is shown, for example, in the embodiments in FIG. 10 and FIG. 11. The areas with which the back side 412 of the circuit board 41 is supported on the webs 8 thus refer to those areas which overlap the webs 8 when viewed in the axial direction A, wherein it is possible but in no way necessary, that these areas are wholly or partially in direct physical contact with the webs 8.

As can be recognized in particular in FIG. 10, a plurality of the circuit breakers 420 is arranged in that area on the front side 411 of the circuit board 41 with which the back side 412 of the circuit board 41 rests on the webs 8. Preferably, all of the circuit breakers 420 are arranged in that area of the circuit board 41 with which the back side 412 of the circuit board 41 rests on the webs 8. Furthermore, thermal connecting elements 85 (FIG. 7) are provided for each circuit breaker 420, which thermally connect the circuit breaker 420 to the web 8 on which that area of the circuit board 41 rests on which the respective circuit breaker 420 is arranged.

Each thermal connecting element 85 is preferably designed as a through-hole plating. The term thermal vias is also commonly used for such through-hole platings. These form thermal bridges which extend from the front side 411 of the circuit board 41 to the back side 412 of the circuit board 41.

Preferably, a plurality of thermal connecting elements 85 is provided for each circuit breaker 420. This is illustrated by the schematic representation in FIG. 7. In the right representation, FIG. 7 shows a detail made of the back side 412 of the circuit board 41, namely the area of the back side 412 where one of the circuit breakers 420 is arranged on the front side 411. A total of sixteen thermal connecting elements 85 are provided, each of which is designed as a through-hole plating, which thermally connects the circuit breaker 420 to the back side 412 of the circuit board 41 and thus to the web 8 on which this area of the circuit board 41 rests. The sixteen thermal connecting elements 85 are arranged in four rows of four thermal connecting elements 85 each. It is understood that the number of sixteen thermal connecting elements 85 per circuit breaker is to be understood as an example. Of course, a larger or a smaller number than sixteen thermal connecting elements 85 per circuit breaker 420 can also be provided.

The left representation in FIG. 7 schematically shows a section through the circuit board 41 with one of the circuit breakers 420 which is arranged on the front side 411 of the circuit board 41. Preferably, a separate mounting surface 421 is provided in each case for each circuit breaker 420 on the front side 411 of the circuit board 41, to which mounting surface the respective circuit breaker 420 is attached, for example by a soldered connection. The mounting surface 421 preferably consists of a material with good thermal conductivity, for example a metallic material.

The circuit breakers 420 typically comprise transistors, preferably MOSFETs, with which half bridges or full bridges are realized that control the windings 61 of the stator 2. Typically, one or more such half-bridge or full-bridge circuits are arranged in the chip housing 424 of the circuit breaker 420, wherein drivers can optionally also be provided in the chip housing 424. The chip housing 424 of the circuit breaker 420 is attached to the mounting surface 421 on the front side 411 of the circuit board 41. Several connection pins are provided (not represented) at the chip housing 424 of the circuit breaker 420, via which the electronic components of the circuit breaker 420, i.e., for example the transistors, can be electrically connected to conductor tracks or electrical connectors on the circuit board 41. The electronic components of the circuit breaker 420 are electrically insulated from the chip housing 424. The mounting surface 421, which also serves as a cooling surface for the circuit breaker 420, is usually at ground potential. The thermal connecting elements 85 extend from the mounting surface 421 through the circuit board 41 to the back side 412 of the circuit board 41.

In the operating state, the circuit breakers 420 represent one of the main heat sources, if not the main heat source, of the control unit 40. Due to the arrangement of the circuit breakers 420 in the areas of the circuit board 41 which rest on the webs 8 in the control housing 102, the heat generated by the circuit breakers can be dissipated very efficiently and reliably via the thermal connecting elements 85 into the webs 8 and thus into the housing 10, so that the control unit 40 in particular is reliably protected from overheating.

As this can be recognized in FIG. 9, additional thermal connecting elements 86 are preferably provided, each of which extends from the front side 411 to the back side of the circuit board 41. The additional thermal connecting elements 86 are arranged outside those areas in which the separate mounting surfaces 421 for the circuit breakers 420 are located. The additional thermal connecting elements 86 serve to selectively dissipate heat from other areas of the front side 411 of the circuit board 41 to the back side 412 of the circuit board 41. These other areas are areas in which no circuit breakers 420 are arranged. The additional thermal connecting elements 86 are also preferably arranged such that they end at the webs 8 or are thermally coupled to the webs 8. Each additional thermal connecting element 86 is preferably designed as a through-hole plating.

It is a further advantageous measure (see FIG. 9) that a contact pad 87 is provided for each mounting surface 421 on the back side 412 of the circuit board, which contact pad thermally couples all the thermal connecting elements 85 belonging to this mounting surface 421 to each other. Each contact pad 87 rests on one of the webs 8. Each contact pad 87 is made of copper, for example. Each contact pad 87 is designed, for example, as a copper film or as a copper layer that thermally connects in each case the ends of all thermal connecting elements 85 belonging to the same circuit breaker 420 to each other on the back side 412 of the circuit board 41. Heat can be dissipated particularly well into the webs 8 and thus into the housing 10 by these large-area contact pads 87.

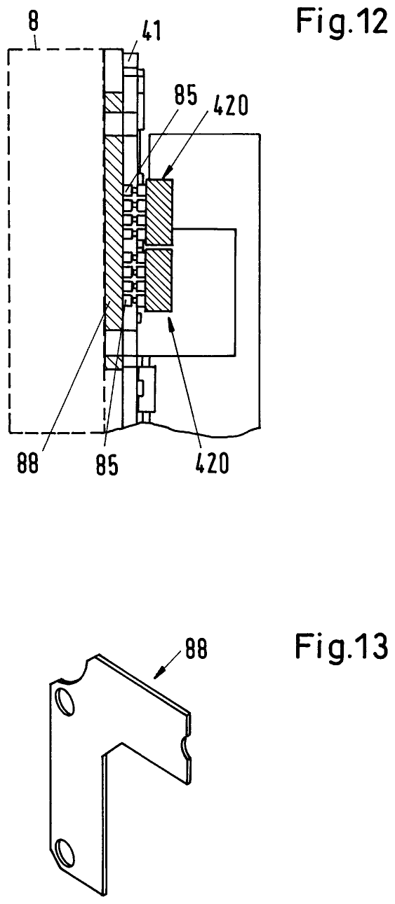

FIG. 11 shows a plan view onto the back side 412 of a variant for the circuit board 41. For better understanding, FIG. 12 shows a schematic sectional view of this variant of the circuit board 41, wherein the section is made along the line XII-XII in FIG. 11.

In this variant, a heat conducting layer 88 is arranged between the back side 412 of the circuit board 41 and the respective web 8 on which the circuit board 41 rests, with which heat can be transferred from the circuit board 41 to the respective web 8 and thus to the housing 10.

For better understanding, FIG. 13 shows a perspective representation of one of the heat conducting layers 88.

Preferably, the shape of the heat conducting layer 88 corresponds to the surface of the web 8 on which the heat conducting layer 88 rests, so that the entire surface of the web 8 on which the circuit board 41 rests is covered by the heat conducting layer 88.

The heat conducting layer 88 improves the thermal connection to the housing 10. Preferably, the heat conducting layer 88 is designed as a film made of a thermally conductive material and is arranged between the circuit board 41 and the respective web 8 on which the circuit board 41 rests. The heat conducting layer 88 designed as a film can be mounted or soldered to the back side 412 of the circuit board 41, for example. It is understood that several heat conducting layers 88 can be provided, so that such a heat conducting layer 88 is arranged between all webs 8 on which the circuit board 41 rests and the circuit board. The heat is transferred over a wide area to the webs 8 and thus to the housing 10 by the heat conducting layers 88, whereby the thermal transition resistance is reduced. The heat conducting layers 88, preferably designed as films, are made of a thermally good conductive and easily deformable (ductile) material, so that the heat conducting layers 88 can also compensate for small unevennesses and mechanical tolerances. Metallic materials, for example copper or silver, are particularly suitable for the heat conducting layers 88. An advantage of designing the heat conducting layers 88 as copper films is that they are easy to solder. In order to further improve the solderability, the copper films can also be coated with a precious metal, for example gold.

In the following, it will be explained how the magnetic levitation device 1 can be assembled in a very simple manner. For example, the assembly can be performed as follows. The sensor board 7 with the magnetic field sensors arranged and attached thereon is inserted into the holding device 9.

Subsequently, the holding device 9 can be completely filled with a potting compound in such a way that the sensor board 7 is completely covered by the potting compound.

The coil cores 25 are lead through the notches 91 in the holding device 9 and through the concentrated windings 61. The magnetic back iron 22 is arranged between the first ends 261 of the longitudinal legs 26. The holding device 9, the back iron 22 and the coil cores 25 with the concentrated windings 61 arranged thereon are inserted into the stator housing 101 of the housing 10 in a first installation direction in axial direction A (according to the representation in FIG. 2 from the left side). In the process, the electrical connecting element 76 is lead parallel to the longitudinal legs 26 of the coil cores 25 through the stator housing 101 into the control housing 102.

When the holding devices 9, the windings 61, the back iron 22 and the coil cores 25 are arranged in the stator housing 101 of the housing 10, the containment can 21 is placed on the housing 10 and connected to the housing 10 in a sealed, preferably hermetically sealed, manner, whereby the seal 201 is arranged between the containment can 21 and the housing 10.

Subsequently, the housing 10 of the magnetic levitation device 1 is filled with a thermally conductive potting compound. The thermal potting compound preferably has a particularly good thermal conductivity in order to quickly and reliably dissipate the heat generated in the operating state into the housing 10, from where the heat is then dissipated mainly by convection. Polyurethanes, epoxy resins, acrylic resins or polyesters, for example, are suitable as the thermally conductive potting compound.

After the stator housing 101 of the housing 10 has been filled with the second potting compound, the control unit 40 is inserted into the control housing 102 of the housing 10 in a second installation direction, wherein the second installation direction is opposite to the first installation direction. According to the representation in FIG. 2, the control unit 40 is thus inserted into the control housing 102 from the right. The electrical connecting element 76 is connected to the control unit 40.

When the control unit 40 is arranged in the control housing 102 of the housing 10, the housing cover 11 is placed on the housing 10 and connected to the housing 10 in a sealed, preferably hermetically sealed, manner, wherein the sealing clement 105 is arranged between the housing cover 11 and the housing 10. The housing cover 11 is attached to the housing 10, for example by several screws 111 (FIG. 1).

Optionally, the control housing 102 of the housing 10 can also be filled with a potting compound, for example for applications with highly corrosive or aggressive or explosive fluids. If the control housing 102 is also filled, this is done before the housing cover 11 is placed on the housing 10 and is firmly connected to it.

The magnetic levitation device 1 according to the disclosure is particularly suitable for centrifugal pumps, as well as for mixing devices for mixing flowable substances, for stirring devices, for example for mixing a fluid in a tank, for fans or also for devices for supporting and rotating wafers, for example in the semiconductor production.

What is claimed is:

1. A magnetic levitation device for contactless magnetic levitation of a rotor, comprising a disk-shaped or ring-shaped magnetically effective core, the magnetic levitation device comprising:
a housing;
a stator;
a controller,
the stator comprising a plurality of coil cores, each of the plurality of coil cords having a longitudinal leg extending from a first end in an axial direction to a second end, and a transverse leg arranged at the second end of the longitudinal leg, and extending in a radial direction perpendicular to the axial direction, a concentrated winding provided at each longitudinal leg of the plurality of coil cores surrounding a respective longitudinal leg, the stator including a cup-shaped recess into which the rotor is capable of being inserted, the cup-shaped recess being arranged at an axial end of the stator,
the controller comprising a circuit board with a front side and a back side, circuit breakers to control the windings arranged on the front side,
the housing comprising an outer wall, a stator housing to receive the stator, a control housing to receive the controller, and a separating wall separating the stator housing from the control housing; and
a web arranged on the separating wall and adjacent to the outer wall, the web projecting into the control housing, the back side of the circuit board supported on the web, the circuit breakers arranged in an area of the circuit board with which the back side of the circuit board is supported on the web, and thermal connecting elements to dissipate heat are provided between the circuit breakers and the web.

2. The magnetic levitation device according to claim 1, wherein the outer wall of the housing, the separating wall and the web are a single-piece unit.

3. The magnetic levitation device according to claim 1, wherein each of the circuit breakers is arranged on a respective separate mounting surface, each of the respective mounting surfaces is connected to the back side of the circuit board via the thermal connecting elements, and each of the thermal connecting elements extends from the front side to the back side of the circuit board.

4. The magnetic levitation device according to claim 3, wherein the thermal connecting elements are a first set of thermal connecting elements and a second set of thermal connecting elements are provided, each of the second set of thermal connecting elements extending from the front side to the back side of the circuit board, and each of the second set of thermal connecting elements is arranged outside the respective mounting surfaces.

5. The magnetic levitation device according to claim 3, wherein for each of the respective mounting surfaces a contact pad is provided on the back side of the circuit board, the contact pad thermally coupling the thermal connecting elements belonging to the respective mounting surfaces to each other.

6. The magnetic levitation device according to claim 1, wherein a heat conducting layer is arranged between the web and the back side of the circuit board, with which heat can be transferred from the circuit board to the housing.

7. The magnetic levitation device according to claim 6, wherein the heat conducting layer is a film attached to the back side of the circuit board.

8. The magnetic levitation device according to claim 6, wherein the heat conducting layer is a metallic material.

9. The magnetic levitation device according to claim 1, wherein the control housing of the housing includes an interior space having a substantially rectangular or square cross-sectional area perpendicular to the axial direction.

10. The magnetic levitation device according to claim 1, wherein the stator housing of the housing includes an interior space having a substantially round cross-sectional area perpendicular to the axial direction.

11. The magnetic levitation device according to claim 1, wherein a housing cover is arranged at one axial end of the magnetic levitation device, the housing cover configured to close the control housing.

12. The magnetic levitation device according to claim 1, wherein the stator comprises a containment can forming one axial end of the stator, the containment can including the cup-shaped recess.

13. The magnetic levitation device according to claim 1, wherein the separating wall comprises an inner cup having a substantially cylindrical configuration and being arranged radially inwardly with respect to the windings in an interior space surrounded by the windings.

14. The magnetic levitation device according to claim 1, wherein the windings are configured to be inserted into the stator housing in a first installation direction in the axial direction, and the controller is configured to be inserted into the control housing in a second installation direction, and the first installation direction is directed in the opposite direction to the second installation direction.

15. The magnetic levitation device according to claim 1, wherein the stator is configured to generate torque with which the rotor is configured to be driven magnetically without contact for rotation about the axial direction.
